(19) United States
(12) Patent Application Publication
(10) Pub. No.: US 2026/0372133 A1
(43) Pub. Date: Nov. 19, 2026

(54) ELECTRONIC DEVICE

(71) Applicant: InnoLux Corporation, Miao Li-County (TW)

(72) Inventors: Chia-Ping TSENG, Miao-Li County (TW); Po-Yun Hsu, Miao-Li County (TW); Ju-Li Wang, Miao-Li County (TW)

(73) Assignee: InnoLux Corporation, Miao-Li County (TW)

(21) Appl. No.: 19/655,658

(22) Filed: Apr. 22, 2026

Related U.S. Application Data
(60) Provisional application No. 63/804,725, filed on May 13, 2025.

(30) Foreign Application Priority Data
Mar. 16, 2026 (CN) 202610318267.8

(51) Int. Cl. H10W 70/63; H10W 46/00; H10W 70/60; H10W 70/66; H10W 90/10; H10W 74/15; H10W 90/00

(52) U.S. Cl. CPC H10W 70/635; H10W 46/607; H10W 70/614; H10W 70/66; H10W 90/10; H10W 74/15; H10W 90/724

(57) ABSTRACT

An electronic device comprises a substrate, two adjacent through-holes penetrating the substrate, a conductive element, a circuit structure, and an electronic unit. The substrate comprises a first surface and a second surface opposite to each other. A first spacing exists between the two adjacent through-holes, and the first spacing is less than or equal to 200 micrometers. The conductive element is disposed in one of the two adjacent through-holes. The circuit structure is disposed on the first surface of the substrate. The electronic unit is disposed on the circuit structure and is electrically connected to the conductive element through the circuit structure, wherein the conductive element comprises a first portion adjacent to the circuit structure. The first portion has a first average grain size measured before the circuit structure is formed on the substrate, and the first average grain size is less than or equal to 5 micrometers.

### CROSS REFERENCE TO RELATED APPLICATION

This application claims the benefit of U.S. Provisional Application No. 63/804,725, filed on May 13^{th}, 2025. The content of the application is incorporated herein by reference.

### BACKGROUND OF THE DISCLOSURE

### 1. FIELD OF THE DISCLOSURE

The present disclosure relates to an electronic device, and more particularly, to an electronic device with good reliability.

### 2. DESCRIPTION OF THE PRIOR ART

In current semiconductor packaging technologies, mounting electronic units with different functions on the same substrate to enhance the performance of an electronic device. This leads to an increase in the thickness of the substrate, which in turn increases the aspect ratio of conductive through-holes penetrating the substrate. This may cause premature closure of the through-hole openings during the manufacturing process, resulting in the formation of voids in the center of the conductive through-holes that adversely affect conductive properties. This makes it difficult for the conductive through-holes to meet current or future reliability requirements.

### SUMMARY OF THE DISCLOSURE

The present disclosure provides an electronic device that can improve the reliability of the electronic device.

According to an embodiment of the present disclosure, an electronic device comprises a substrate, two adjacent through-holes penetrating the substrate, a conductive element, a circuit structure, and an electronic unit. The substrate comprises a first surface and a second surface opposite to each other in a first direction. A first spacing exists between the two adjacent through-holes, and the first spacing is less than or equal to 200 micrometers. The conductive element is disposed in one of the two adjacent through-holes. The circuit structure is disposed on the substrate. The electronic unit is disposed on the circuit structure and is electrically connected to the conductive element through the circuit structure, wherein the conductive element comprises a first portion adjacent to the circuit structure. In a cross-sectional view, the first portion has a first average grain size measured before the circuit structure is formed on the substrate, and the first average grain size is less than or equal to 5 micrometers.

Based on the foregoing, in the electronic device of the embodiments of the present disclosure, the conductive element comprises a first portion adjacent to the circuit structure, and in a cross-sectional view, the first portion has a first average grain size measured before the circuit structure is formed on the substrate, wherein the first average grain size is less than or equal to 5 micrometers. As a result, the conductive element formed in the through-hole can fill the through-hole well, which can reduce the formation of voids in the center of the conductive element that adversely affect conductive properties. It can also reduce the probability of substrate cracking due to differences in the coefficient of thermal expansion (CTE) between the substrate and the conductive element, thereby improving the reliability of the electronic device.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic cross-sectional view of an electronic device according to an embodiment of the present disclosure.

FIG. 2 is an enlarged schematic view of region A in FIG. 1 according to an embodiment.

FIG. 3 is a flowchart of a manufacturing method for an electronic device according to an embodiment of the present disclosure.

FIGS. 4 and 5 are schematic cross-sectional views of a manufacturing method for a conductive element according to an embodiment of the present disclosure.

FIGS. 6, 7 and 8 are schematic cross-sectional views of conductive elements according to different embodiments of the present disclosure.

FIG. 9 is a schematic cross-sectional view of an electronic device according to another embodiment of the present disclosure.

### DETAILED DESCRIPTION

The present disclosure can be understood by reference to the following detailed description, taken in conjunction with the accompanying drawings. It should be noted that for ease of understanding for the reader and for the conciseness of the drawings, many of the drawings in the present disclosure show only a portion of the package structure, and specific elements in the drawings are not drawn to actual scale. In addition, the number and size of each element in the drawings are for illustrative purposes only and are not intended to limit the scope of the present disclosure. For example, for the sake of clarity, the relative size, thickness, and position of each film, region, and/or structure may be reduced or exaggerated.

Certain terms are used throughout the specification and appended claims to refer to specific components. Those skilled in the art will understand that electronic device manufacturers may refer to the same component by different names. This document does not intend to distinguish between components that differ in name but not in function. In the following description and claims, the words “comprising” and “including” are open-ended terms and should be interpreted to mean “including but not limited to...”.

Herein, "an element is disposed on another element" is for the convenience of describing the relative position between the element and the another element, and is not intended to limit the process steps or sequence of the element and the another element.

The directional terms mentioned herein, such as "upper," "lower," "front," "rear," "left," "right," etc., are only for referencing the directions in the drawings. Therefore, the directional terms used are for illustrative purposes and not for limiting the present disclosure. It should be understood that when an element or layer is referred to as being "on" or "connected to" another element or layer, it can be directly on or connected to the other element or layer, or intervening elements or layers may be present (indirect case). In contrast, when an element is referred to as being "directly on" or "directly connected to" another element, there are no intervening elements or layers present. In addition, when an element or layer is referred to as being overlapped with another element, the element or layer is at least partially overlapped with the another element or layer.

The terms "about," "approximately," "substantial," or "substantially" as used herein generally mean within 10%, 5%, 1%, or 0.5% of a given value or range. Furthermore, the phrases "a given range is from a first value to a second value" or "a given range falls within the range of a first value to a second value" indicate that the given range includes the first value, the second value, and other values therebetween.

In some embodiments of the present disclosure, terms related to joining and connection, such as "connected" and "interconnected," unless specifically defined otherwise, may refer to two structures being in direct contact, or they may also refer to two structures not being in direct contact, with other structures disposed between them. Terms related to joining and connection may also include cases where both structures are movable or both structures are fixed. In addition, the terms "electrically connected" and "coupled" include any direct and indirect means of electrical connection.

In the following embodiments, the same or similar elements will be denoted by the same or similar reference numerals, and their redundant descriptions will be omitted. In addition, terms such as "first" and "second" mentioned in this specification or claims are only used to name different elements or to distinguish different embodiments or scopes, and are not intended to limit the upper or lower number of elements, nor to limit the manufacturing sequence or arrangement order of elements.

In the present disclosure, the thickness, length, and width can be optionally measured using an optical microscope (OM) and/or a scanning electron microscope (SEM), but are not limited thereto. In addition, there may be a certain error between any two values or directions used for comparison. If a first value is equal to a second value, it implies that there may be an error of about 10% between the first value and the second value.

The process of the electronic device in the present disclosure can be applied, for example, to a wafer-level package (WLP) process or a panel-level package (PLP) process, and can be chip-first or chip-last (RDL first). The electronic device of the present disclosure can be applied to a power module, a semiconductor package device, a display device, a light-emitting device, a backlight device, an antenna device, a silicon photonics co-packaged device, a sensing device, or a tiling device, but is not limited thereto. The electronic device may comprise package devices such as High Bandwidth Memory (HBM) packages, Chip on Wafer on Substrate (CoWoS) package structures, System on a Chip (SoC), System in a Package (SiP), antenna in package (AiP), Co-packaged Optics (CPO), or various combinations of the above, but is not limited thereto.

The following are exemplary embodiments of the present disclosure, and the same element symbols are used in the drawings and description to represent the same or similar parts.

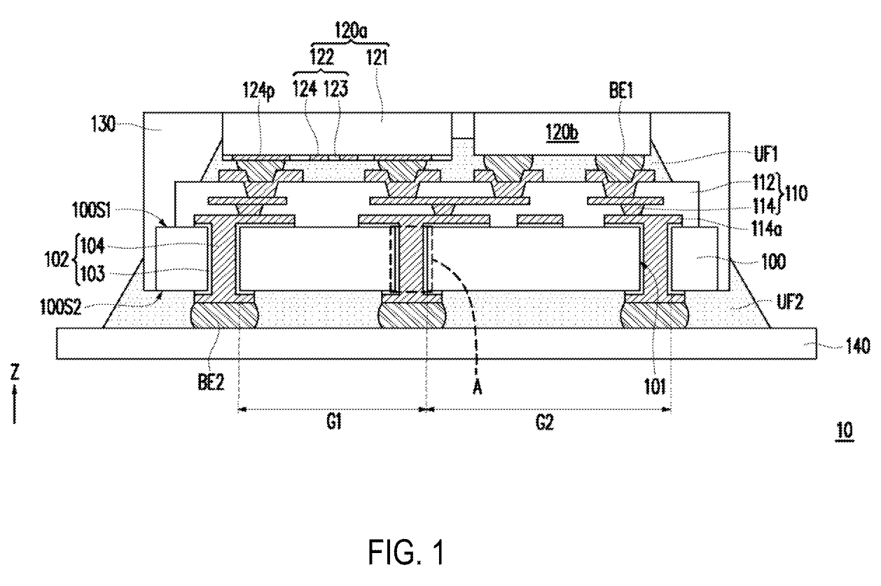

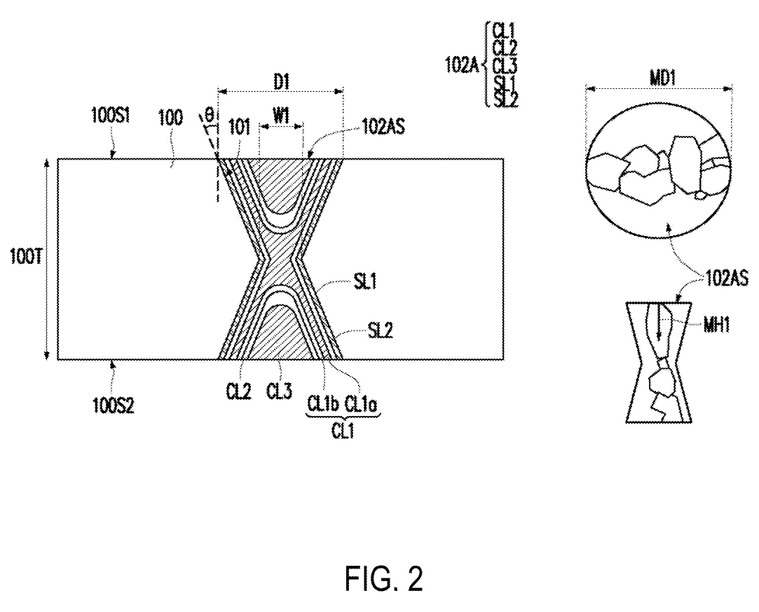

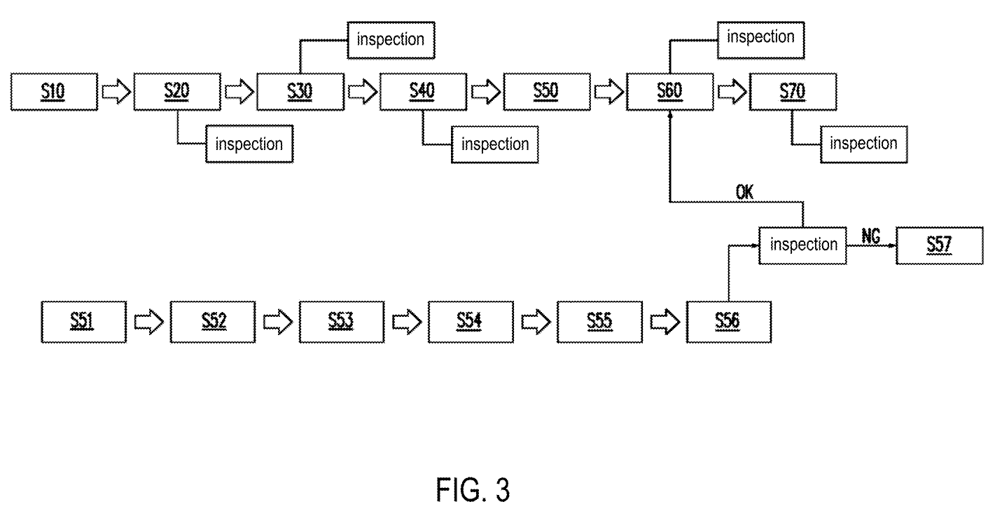

FIG. 1 is a schematic cross-sectional view of an electronic device according to an embodiment of the present disclosure. FIG. 2 is an enlarged schematic view of region A in FIG. 1 according to an embodiment. FIG. 3 is a flowchart of a manufacturing method for an electronic device according to an embodiment of the present disclosure.

Please refer to FIG. 1. The electronic device 10 may comprise a substrate 100, two adjacent through-holes 101 penetrating the substrate 100, a conductive element 102, a circuit structure 110, and an electronic unit 120a or 120b.

The substrate 100 may comprise glass fiber, glass, silicon, or other suitable substrate materials. In some embodiments, the substrate 100 may be a glass substrate comprising glass. In some embodiments, the substrate 100 may serve as a carrier substrate for carrying the electronic unit 120a or 120b, but is not limited thereto. The substrate 100 may comprise a first surface 100S1 and a second surface 100S2 opposite to each other in a first direction (e.g., the Z-direction). In some embodiments, in the Z-direction, the thickness of a single piece of the substrate 100 (thickness 100T as shown in FIG. 2) may range from 40 µm to 1500 µm. In some embodiments, multiple pieces of the substrate 100 may be comprised. In some embodiments, the light transmittance of the substrate 100 may be at least greater than or equal to 90%, where the light may include white light. In some embodiments, the coefficient of thermal expansion (CTE) of the substrate 100 may range from 2 ppm/°C to 10 ppm/°C, which can, for example, buffer the risk of warpage that may be caused when subsequent elements are formed on and/or in the substrate 100.

The through-holes 101 can be formed by performing a drilling process, an etching process, or a combination thereof on the substrate 100. For example, a laser drilling process can be performed on the first surface 100S1 and the second surface 100S2 of the substrate 100 to form the through-holes 101 penetrating the substrate 100. Alternatively, a laser drilling process can be performed from at least one of the first surface 100S1 and the second surface 100S2 of the substrate 100 to form the through-holes 101 penetrating the substrate 100, but it is not limited thereto. In other embodiments, a modification process (such as a laser modification process) and an etching process can be performed from at least one of the first surface 100S1 and the second surface 100S2 of the substrate 100 to form the through-holes 101 in the substrate 100. In some embodiments, the etching process may comprise acid etching, alkaline etching, or a combination thereof.

In the embodiment shown in FIG. 1, along a direction perpendicular to the Z-direction, a first spacing G1 of less than or equal to 200 micrometers exists between two adjacent through-holes 101. In some embodiments, the electronic device 10 further comprises another through-hole (e.g., the through-hole 101 on the right) penetrating the substrate 100 and adjacent to a first through-hole (e.g., the through-hole 101 in the middle) of the two adjacent through-holes 101, wherein a second spacing G2 exists between the another through-hole 101 and the first through-hole 101. In this embodiment, the second spacing G2 is less than or equal to 200 micrometers and can be different from the first spacing G1.

In the embodiment shown in FIG. 2, an included angle θ between an extension line of a sidewall of the through-hole 101 and a normal line (the Z-direction) perpendicular to the first surface 100S1 and the second surface 100S2 of the substrate 100 may be greater than or equal to 0 degrees and less than or equal to 20 degrees. In the schematic cross-sectional view shown in FIG. 2, the through-hole 101 has a first dimension D1 at the first surface 100S1 or the second surface 100S2 of the substrate 100, and a second dimension W1 at a waist portion between the first surface 100S1 and the second surface 100S2. In some embodiments, the first dimension D1 may be the maximum width of the through-hole 101 in a horizontal direction parallel to the first surface 100S1 and the second surface 100S2, and the second dimension W1 may be the minimum width of the through-hole 101 in that horizontal direction. In some embodiments, the extension line of the sidewall of the through-hole 101 may be an extension line between the position of the minimum width and the position of the maximum width. In some embodiments, the first dimension D1 may range from 20 micrometers to 120 micrometers. In some embodiments, the second dimension W1 may range from 15 micrometers to 115 micrometers. In some embodiments, the sidewall of the through-hole 101 may have a first roughness, and the first surface 100S1 and the second surface 100S2 of the substrate 100 may have a second roughness and a third roughness, respectively, wherein the first roughness may be less than the second roughness and the third roughness. With the above design, the skin effect of the electronic device 10 can be reduced, but it is not limited thereto.

The conductive element 102 is disposed in at least one of the two adjacent through-holes 101. In the embodiment shown in FIG. 1, there may be multiple conductive elements 102, and they are respectively disposed in the two adjacent through-holes 101. The conductive element 102 may comprise a seed layer 103 disposed on the sidewall of the through-hole 101 and a conductive layer 104 disposed on the seed layer 103. In some embodiments, the seed layer 103 and the conductive layer 104 may be disposed on at least a portion of the first surface 100S1 and/or at least a portion of the second surface 100S2 of the substrate 100 and extend into the through-hole 101. In some embodiments, the seed layer 103 can be formed by processes such as chemical vapor deposition (CVD), sputtering, atomic layer deposition (ALD), other suitable deposition methods, or a combination of the foregoing. The seed layer 103 may comprise any suitable conductive material, such as titanium (Ti), titanium nitride (TiN), tungsten (W), nickel (Ni), tantalum (Ta), nitrides, carbides, other suitable metals, or their alloys or combinations of the foregoing materials. In some embodiments, the seed layer 103 may be in direct contact with the substrate 100. In some embodiments, the conductive layer 104 can be formed by, for example, electroplating, CVD, sputtering, ALD, resistance heating evaporation, electron beam evaporation, other suitable deposition methods, or a combination of the foregoing. The conductive layer 104 may comprise a conductive material such as copper (Cu). In some embodiments, the conductive layer 104 can be formed by growing the seed layer 103 through an electroplating process.

In the embodiment shown in FIG. 2, the conductive element 102A may comprise a seed layer SL1 and a seed layer SL2 sequentially disposed on the sidewall of the through-hole 101, and a first conductive layer CL1, a second conductive layer CL2, and a third conductive layer CL3 sequentially disposed on the seed layer SL2. The seed layer SL1 and the seed layer SL2 may each comprise the materials listed for the aforementioned seed layer 103. The first conductive layer CL1, the second conductive layer CL2, and the third conductive layer CL3 may each comprise the materials listed for the aforementioned conductive layer 104. In this embodiment, the first conductive layer CL1 comprises a bridge layer CL1a formed on the seed layer SL2 and a first layer CL1b formed on the bridge layer CL1a. In the cross-sectional view shown in FIG. 2, the bridge layer CL1a may comprise a bridge portion formed at the waist portion of the through-hole 101 (e.g., at the waist portion having the second dimension W1) to bridge the seed layers formed on the left and right sidewalls of the through-hole 101 in the cross-sectional view. In the embodiment shown in FIG. 2, the bridge layer CL1a may fill the waist of the through-hole 101, such that the subsequently formed first layer CL1b, second conductive layer CL2, and third conductive layer CL3 are respectively formed on the upper surface of the bridge layer CL1a (i.e., the surface facing the first surface 100S1) and the lower surface of the bridge layer CL1a (i.e., the surface facing the second surface 100S2).

In some embodiments, please refer to FIGS. 2 and 3, the through-hole 101 and the conductive element 102A can be formed by the following steps. First, step S10 is performed to provide the substrate 100. Next, step SCL1b is performed to conduct a modification process on at least one of the first surface 100S1 and the second surface 100S2 of the substrate 100. Then, step S30 is performed to conduct an etching process on the modified substrate 100 to form the through-hole 101. Afterward, step S50 is performed to form the conductive element 102A in the through-hole 101. In some embodiments, step S50 may comprise the following steps. First, step S51 of forming seed layers is executed to sequentially form the seed layer SL1 and the seed layer SL2 on the sidewall of the through-hole 101. Next, step S52 of forming the bridge layer CL1a is executed to form the bridge layer CL1a on the seed layer SL2. In some embodiments, the bridge layer CL1a can be formed by growing the seed layer SL2 using an electroplating process with a first current density. Then, step S53 of forming the first layer CL1b is executed to form the first layer CL1b on the bridge layer CL1a. In some embodiments, the first layer CL1b can be formed on the bridge layer CL1a using an electroplating process with a second current density. In some embodiments, the second current density can be greater than the first current density. Afterward, step S54 of forming the second conductive layer CL2 is executed to form the second conductive layer CL2 on the first layer CL1b. In some embodiments, the second conductive layer CL2 can be formed on the first layer CL1b using an electroplating process with a third current density. In some embodiments, the third current density can be greater than the first current density. Then, step S55 of forming the third conductive layer CL3 is executed to form the third conductive layer CL3 on the second conductive layer CL2. In some embodiments, the third conductive layer CL3 can be formed on the second conductive layer CL2 using an electroplating process with a fourth current density. In some embodiments, the fourth current density can be greater than the first current density. Afterward, step S56 is executed to remove the portions of the seed layer SL1, the seed layer SL2, the first conductive layer CL1, the second conductive layer CL2, and the third conductive layer CL3 that are on the first surface 100S1 and the second surface 100S2 of the substrate 100, such that the seed layer SL1, the seed layer SL2, the first conductive layer CL1, the second conductive layer CL2, and the third conductive layer CL3 have an upper surface and a lower surface that are aligned with the first surface 100S1 and the second surface 100S2, respectively. In some embodiments, step S56 may be a step of performing a planarization process such as chemical mechanical polishing (CMP).

In this embodiment, the first current density for forming the bridge layer CL1a is less than the second, third, and fourth current densities. This allows the formed bridge layer CL1a to comprise a bridge portion that can bridge the seed layers SL2 on the left and right sidewalls of the through-hole 101 in a cross-sectional view. The bridge portion is disposed at the waist of the through-hole 101, which can, for example, reduce the formation of voids in the center of the conductive element 102A that adversely affect conductive properties, thereby enhancing the reliability of the electronic device 10.

Please refer to FIG. 2. The conductive element 102A comprises a first portion adjacent to where the circuit structure 110 will be subsequently formed. In the embodiment shown in FIG. 1, the circuit structure 110 is subsequently formed on the first surface 100S1 of the substrate 100, so the first portion can be, for example, a portion adjacent to the first surface 100S1. In other embodiments, the first portion can also comprise a portion adjacent to the second surface 100S2. In a cross-sectional view, the first portion has a first average grain size measured before the circuit structure 110 is formed on the substrate 100, and the first average grain size is less than or equal to 5 micrometers. The first average grain size is the average grain size of grains measured from a surface 102AS of the conductive element 102A downward to a measurement depth MH1 of about 50 micrometers. In this embodiment, relative to the first conductive layer CL1 and the second conductive layer CL2, the third conductive layer CL3 is formed in the center of the conductive element 102A and occupies most of the horizontal area of the conductive element 102A at the first surface 100S1 or the second surface 100S2. That is, in this embodiment, the first average grain size is the average grain size of grains measured from the surface of the third conductive layer CL3 downward to a measurement depth MH1 of about 50 micrometers. In some embodiments, a ratio of the first dimension D1 to the first average grain size ranges from 4 to 24. In some embodiments, a ratio of the second dimension W1 to the first average grain size ranges from 3 to 23. In some embodiments, in a top view, the first portion has a second average grain size measured before the circuit structure 110 is formed on the substrate 100, and the second average grain size is less than or equal to 6 micrometers. The second average grain size is the average grain size of grains measured on a horizontal area of the surface 102AS of the conductive element 102A with a measurement diameter MD1 of about 50 micrometers. In this embodiment, relative to the first conductive layer CL1 and the second conductive layer CL2, the third conductive layer CL3 is formed in the center of the conductive element 102A and occupies most of the horizontal area of the conductive element 102A at the first surface 100S1 or the second surface 100S2. That is, in this embodiment, the second average grain size is the average grain size of grains measured on a horizontal area of the surface of the third conductive layer CL3 with a measurement diameter MD1 of about 50 micrometers. In some embodiments, the first average grain size and the second average grain size are measured when a ratio of the thickness 100T of the substrate 100 to the first dimension D1 of the through-hole 101 is greater than or equal to 6 and less than or equal to 16, and the spacing between two adjacent through-holes 101 is less than or equal to 200 micrometers. Within the described measurement range, the conductive element 102A can be well-formed in the through-hole 101, which can, for example, reduce the formation of voids in the center of the conductive element that adversely affect conductive properties, and can also reduce the risk of substrate cracking caused by the difference in the coefficient of thermal expansion (CTE) between the substrate and the conductive element, thereby improving the reliability of the electronic device.

In some embodiments, after the conductive element 102A as shown in FIG. 2 is formed, an inspection can be performed on the conductive element 102A. If it meets the aforementioned first average grain size and second average grain size and has no other defects, the subsequent step S60 of forming the circuit structure 110 and the subsequent step S70 of a singulation process can be performed. In some embodiments, if a defect that does not meet preset requirements is detected in the conductive element 102A, a repair step S57 can be performed. In some embodiments, step S57 may comprise performing a rework process on the defective conductive element 102A. For example, if the defect is a void in the center of the conductive element 102A that adversely affects conductive properties, a portion of the conductive element 102A can be removed to form an opening that exposes the void. Then, a conductive material is formed in the opening and the void to repair the conductive element 102A. The repaired conductive element 102A may comprise a rework layer (not shown) that fills the aforementioned opening and void. In some embodiments, the process for forming the rework layer may comprise an injection process, chemical plating, a reflow process, or a combination thereof. In some embodiments, after steps SCL1b, S30, S40, S60, and S70 are completed, an inspection step can be performed to ensure that the formed electronic device 10 has good reliability.

Please continue to refer to FIG. 1. The circuit structure 110 may be disposed on the substrate 100. The circuit structure 110 may comprise an insulating layer 112 formed on the substrate 100 and a wiring structure 114 formed in the insulating layer 112. The insulating layer 112 may comprise multiple insulating layers alternately stacked in the Z-direction. The wiring structure 114 may comprise multiple conductive patterns alternately stacked in the Z-direction and formed in the insulating layer 112, and conductive vias connecting the conductive patterns. The wiring structure 114 may comprise any suitable conductive material, such as copper, titanium, nickel, a combination of the above materials, or an alloy thereof, but is not limited thereto. The insulating layer 112 may comprise an organic material or an inorganic material. The organic material includes polyimide (PI), poly-p-xylylene (also known as Parylene), benzocyclobutene (BCB), epoxy resin (epoxy), polycarbonate (PC), polyethylene terephthalate (PET), polyethylene naphthalate (PEN), polymer, or other suitable organic materials, but is not limited thereto. The inorganic material includes silicon oxide, silicon nitride, silicon oxynitride, nitride, oxide, carbide, or other suitable inorganic materials, but is not limited thereto. According to some embodiments, another circuit structure may be disposed on a side of the substrate 100 opposite to the circuit structure 110, that is, it can be disposed on the second surface 100S2.

In some embodiments, in a cross-sectional view, the first portion of the conductive element 102 adjacent to the circuit structure 110 has a first grain size distribution measured after the circuit structure 110 is formed on the substrate 100, and the first grain size distribution ranges from 0.1 micrometers to 20 micrometers. In the embodiment shown in FIG. 2, the first grain size distribution is the grain size distribution measured on a horizontal area of the surface 102AS of the conductive element 102A with a measurement diameter MD1 of about 50 micrometers and from the surface 102AS of the conductive element 102A downward to a measurement depth MH1 of about 50 micrometers. Since subsequent processes, such as the thermal process for forming the circuit structure 110, may affect the grain size of the conductive element 102 and thus cause the substrate 100 to crack, controlling the size of the conductive element 102 as described above can reduce the risk of substrate 100 cracking.

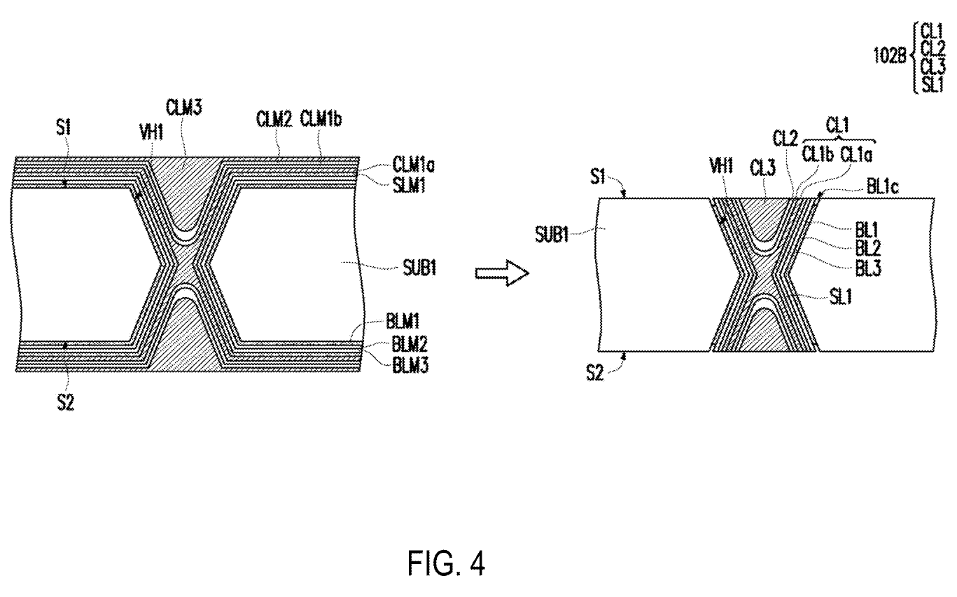

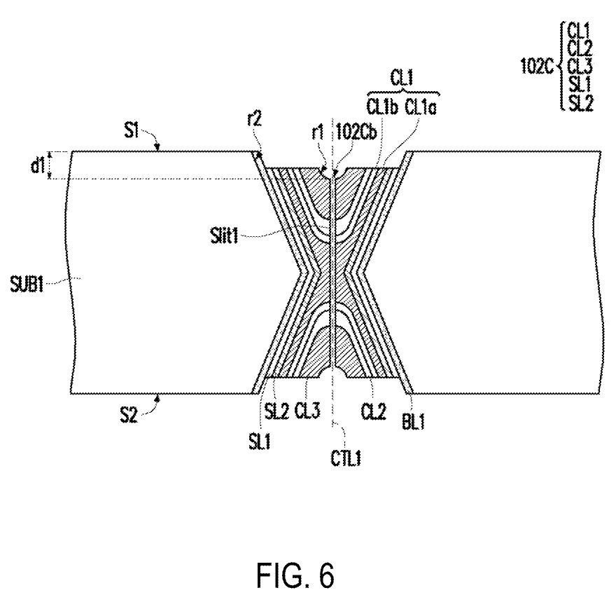

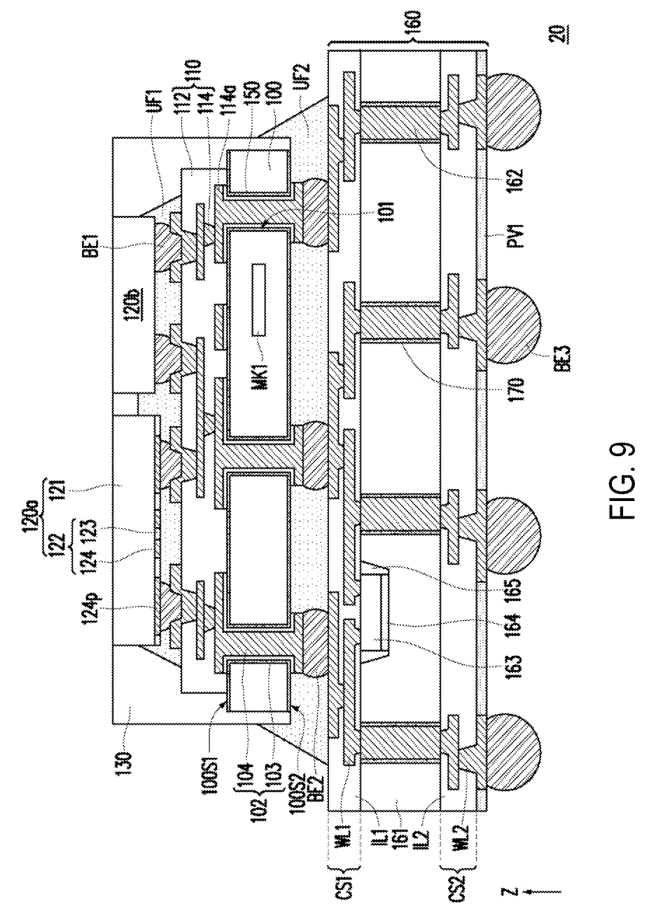

As shown in FIG. 4, in a direction perpendicular to the Z-direction, a buffer layer is disposed between the substrate 100 and the conductive element 102. The buffer layers are BL1, BL2, and BL3, the buffer layer BL1 shown in FIGS. 6-8, and the buffer layer 150 shown in FIG. 9. In embodiments comprising a buffer layer, the first portion of the conductive element 102 adjacent to the circuit structure 110 has a first grain size distribution measured after the circuit structure 110 is formed on the substrate 100, and the first grain size distribution ranges from 20 micrometers to 60 micrometers. This is because the buffer layer can help mitigate the CTE difference between the substrate 100 and the conductive element 102. This allows the lower limit of the aforementioned first grain size distribution to be increased to 20 micrometers and the upper limit to be increased to 60 micrometers, which helps to increase the process margin.

The electronic unit 120a or 120b may be disposed on the circuit structure 110 and electrically connected to the conductive element 102 through the circuit structure 110. The electronic units 120a or 120b may be the same as or different from each other and each may comprise a die, a chip, a diode, an antenna unit, a memory unit, a photonic integrated circuit (PIC) unit, a sensor, or a structure from a semiconductor-related process. In some embodiments, the electronic unit 120a may comprise a base layer 121 and a circuit layer 122. The base layer 121 may comprise a semiconductor material used for a semiconductor substrate, such as silicon. The circuit layer 122 may comprise at least one insulating layer 123 and at least one wiring layer 124 formed in the insulating layer 123. The material of the insulating layer 123 may be similar to the materials listed for the aforementioned insulating layer 112, and the material of the wiring layer 124 may be similar to the materials listed for the aforementioned wiring structure 114. In this embodiment, the base layer 121 may comprise a first side on or in which connection pads (e.g., connection pads 124p in the wiring layer 124) for signal transmission are disposed, and a second side opposite to the first side in the Z-direction, wherein the circuit layer 122 may be disposed at the first side of the base layer 121. In some embodiments, the connection pads for signal transmission may be, for example, input/output pads.

In some embodiments, the electronic device 10 may comprise a bonding element BE1 disposed between the electronic unit 120a or 120b and the circuit structure 110. The electronic unit 120a or 120b can be electrically connected to the circuit structure 110 through the bonding element BE1. In some embodiments, the bonding element BE1 may comprise solder balls. In some embodiments, the material of the bonding element BE1 may comprise tin-silver (SnAg), tin, silver, nickel, gold, copper, conductive adhesive, or other suitable conductive materials, but is not limited thereto. In some embodiments, the electronic device 10 may comprise a bonding element BE1 disposed between the electronic unit 120a or 120b and the circuit structure 110, and the bonding element BE1 may be formed by a portion of the connection pads 124p and a portion of the wiring structure 114 in the circuit structure 110 to achieve hybrid bonding.

In some embodiments, the electronic device 10 may comprise a connection component 140 and a bonding element BE2 disposed between the connection component 140 and the substrate 100. The connection component 140 can be electrically connected to the conductive element 102 through the bonding element BE2. In some embodiments, the connection component 140 may be a printed circuit board (PCB). In some embodiments, the material of the bonding element BE2 may be similar to the materials listed for the aforementioned bonding element BE1.

In some embodiments, the electronic device 10 may comprise a protective layer UF1 disposed between the electronic unit 120a or 120b and the substrate 100 and surrounding at least one of the plurality of bonding elements BE1 to enhance the reliability of the electronic device 10. The protective layer UF1 may comprise any suitable underfill material. In some embodiments, the electronic device 10 may comprise a protective layer UF2 disposed between the substrate 100 and the connection component 140 and surrounding at least one of the plurality of bonding elements BE2 to enhance the reliability of the electronic device 10. The protective layer UF2 may comprise any suitable underfill material. In this embodiment, "an element surrounds another element" may mean that the element is in contact with at least a side surface of the another element in a cross-sectional view. For example, as shown in FIG. 1, the protective layer UF1 may be in contact with a side surface of the bonding element BE1, and the protective layer UF2 may be in contact with a side surface of the bonding element BE2.

In some embodiments, the electronic device 10 may comprise an encapsulation layer 130 on the substrate 100 that surrounds the electronic unit 120a, the electronic unit 120b, and the circuit structure 110. The encapsulation layer 130 can prevent the electronic units 120a and 120b from being affected by external moisture, thereby improving the reliability of the electronic device 10. The encapsulation layer 130 may comprise any suitable encapsulation material, such as epoxy molding compound (EMC), but is not limited thereto. In some embodiments, the encapsulation layer 130 may also extend onto the side surfaces of the substrate 100 that connect the first surface 100S1 and the second surface 100S2. This can help control the degree of warpage of the substrate 100, thereby enhancing the reliability of the electronic device 10. In some embodiments, the encapsulation layer 130 may surround the side surfaces of the substrate 100. As a result, when the substrate 100 is a glass substrate, the encapsulation layer 130 can provide an additional protective effect to prevent the substrate 100 from being damaged by stress, such as that caused by CTE differences.

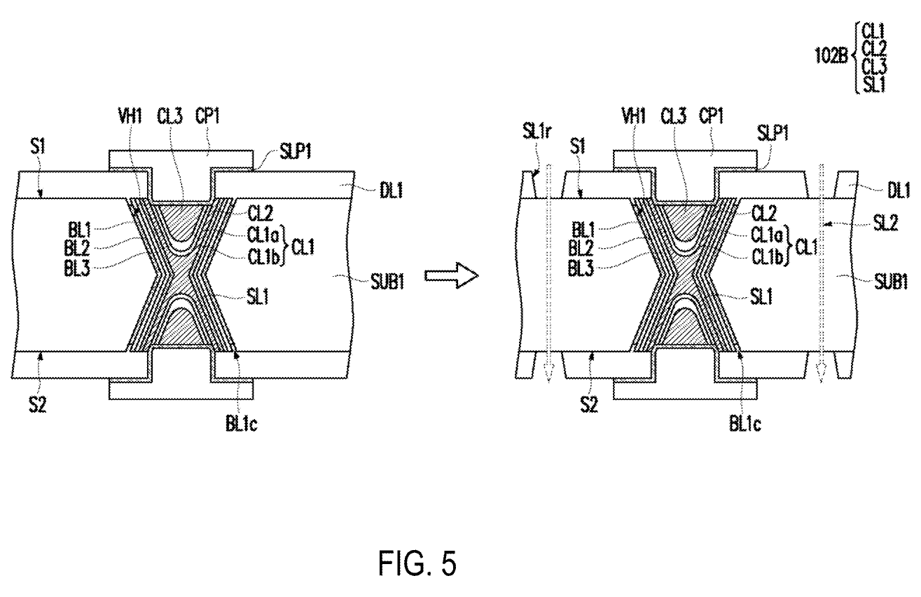

FIGS. 4 and 5 are schematic cross-sectional views of a manufacturing method for a conductive element according to an embodiment of the present disclosure. The conductive element 102B shown in FIGS. 4 and 5 is similar to the conductive element 102A shown in FIG. 2, with the difference being that a buffer layer exists between the seed layer SL1 of the conductive element 102B and the substrate 100 (i.e., it also includes a step S40 of forming a buffer layer). Other same or similar elements are denoted by the same or similar element symbols, and their redundant descriptions are not repeated here.

Please refer to FIG. 4. On an upper surface S1 and a lower surface S2 of a substrate SUB1, a buffer material layer BLM1, a buffer material layer BLM2, and a buffer material layer BLM3 are sequentially formed, extending into a through-hole VH1. In some embodiments, the buffer material layer BLM1, the buffer material layer BLM2, and the buffer material layer BLM3 may comprise an organic material or an inorganic material. In some embodiments, a buffer material layer BLM1, a buffer material layer BLM2, and a buffer material layer BLM3 may comprise the same or different materials.

Next, on the buffer material layer BLM3, a seed material layer SLM1, a bridge material layer CLM1a, a first material layer CLM1b, a second conductive material layer CLM2, and a third conductive material layer CLM3 are sequentially formed. Then, a planarization process is used to remove the portions of the buffer material layer BLM1, the buffer material layer BLM2, the buffer material layer BLM3, the seed material layer SLM1, the bridge material layer CLM1a, the first material layer CLM1b, the second conductive material layer CLM2, and the third conductive material layer CLM3 that are on the upper surface S1 and the lower surface S2 of the substrate SUB1. This forms a buffer layer BL1, a buffer layer BL2, a buffer layer BL3, a seed layer SL1, a bridge layer CL1a, a first layer CL1b, a second conductive layer CL2, and a third conductive layer CL3. In some embodiments, the buffer layer BL1, the buffer layer BL2, the buffer layer BL3, the seed layer SL1, the bridge layer CL1a, the first layer CL1b, the second conductive layer CL2, and the third conductive layer CL3 may have surfaces that are aligned with the upper surface S1 and the lower surface S2, respectively, but it is not limited thereto. For example, as shown in FIG. 4, the buffer layer BL1 may have a recess BL1c whose surface may be lower than the upper surface S1 and the lower surface S2. The method of forming buffer layer BL including sputter, deposition, plasma, coating, screening, or various combinations of the above. A surface roughness of the BL is less than the first roughness of the sidewall of the through-hole 101, and the roughness of the BL is less than or equal to 0.1μm to improve the adhesion with the conductive element 102.

In this embodiment, the buffer layer BL1, the buffer layer BL2, and the buffer layer BL3 can be disposed between the substrate SUB1 and the seed layer SL1 of the conductive element 102B to help ameliorate the negative effects on the substrate SUB1 caused by the process of forming the through-hole VH1 (or through-hole 101). For example, the buffer layer BL1, the buffer layer BL2, and the buffer layer BL3 can repair defects (such as micro-cracks) generated when the through-hole VH1 is formed in the substrate SUB1 through a modification process and an etching process. In other embodiments, for example, when the substrate SUB1 is a glass substrate, the buffer layer BL1, the buffer layer BL2, and the buffer layer BL3 can mitigate the CTE difference between the substrate SUB1 and the conductive element 102B subsequently formed in the through-hole VH1, thereby improving the adhesion of the conductor layer formed in the through-hole VH1. In this embodiment, there can be 3 buffer layers between the substrate SUB1 and the seed layer SL1 of the conductive element 102B, but the present disclosure is not limited thereto. In other embodiments, there can also be a single buffer layer between the substrate SUB1 and the seed layer SL1 of the conductive element 102B (e.g., the buffer layer 150 or buffer layer 170 shown in FIG. 9). In this embodiment, the buffer layer BL1, the buffer layer BL2, and the buffer layer BL3 do not include portions extending onto the upper surface S1 and the lower surface S2 of the substrate SUB1, but the present disclosure is not limited thereto. In other embodiments, as shown in FIG. 9, the buffer layer 150 can be disposed on the sidewall of the through-hole 101 and extend onto the first surface 100S1 and the second surface 100S2 of the substrate 100.

Then, please refer to FIG. 5. After the conductive element 102B is formed, circuit structures are formed on the upper surface S1 and the lower surface S2 of the substrate SUB1. In this embodiment, the circuit structure may comprise an insulating layer DL1 disposed on the upper surface S1 and the lower surface S2 of the substrate SUB1, and a wiring layer (corresponding to the wiring layer 114a shown in FIG. 1) disposed in the insulating layer DL1 and electrically connected to the conductive element 102B. In this embodiment, the wiring layer shown in FIG. 5 may comprise a seed layer pattern SLP1 in contact with the conductive element 102B and a conductive pattern CP1 disposed on the seed layer pattern SLP1. In some embodiments, the insulating layer DL1 may comprise the materials listed for the aforementioned insulating layer 112, the seed layer pattern SLP1 may comprise the materials listed for the aforementioned seed layer 103, and the conductive pattern CP1 may comprise the materials listed for the aforementioned wiring structure 114.

Afterward, after the circuit structure is formed, a singulation process step (e.g., step S70 shown in FIG. 3) can be performed to form singulated structures. In some embodiments, the substrate 100 and the circuit structure 110 shown in FIG. 1 may be one aspect of a singulated structure, but it is not limited thereto. In some embodiments, step S70 may comprise the following steps. First, a scribe line trench SCL1r is formed in the insulating layer DL1 of the circuit structure, exposing the upper surface S1 and the lower surface S2 of the substrate SUB1. Next, cutting is performed along a scribe line SCL2 through the scribe line trench SCL1r, or cutting is performed simultaneously from above and below through the scribe line trench SCL1r, to form multiple singulated structures.

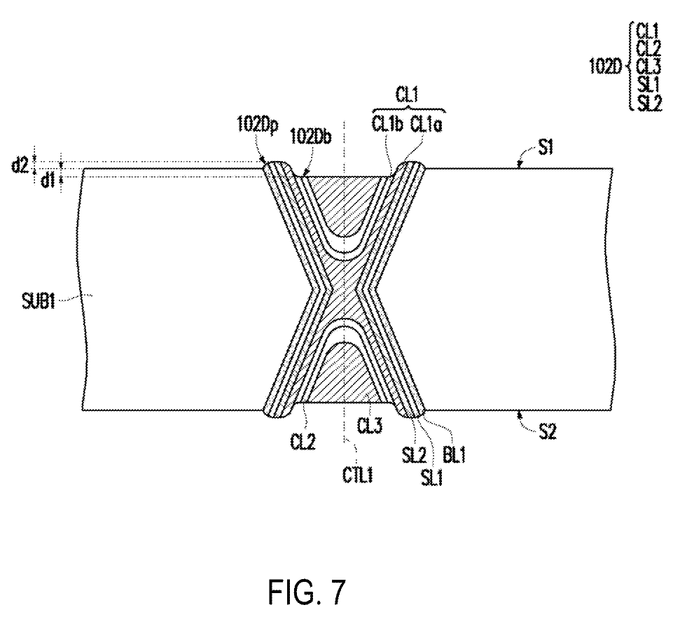

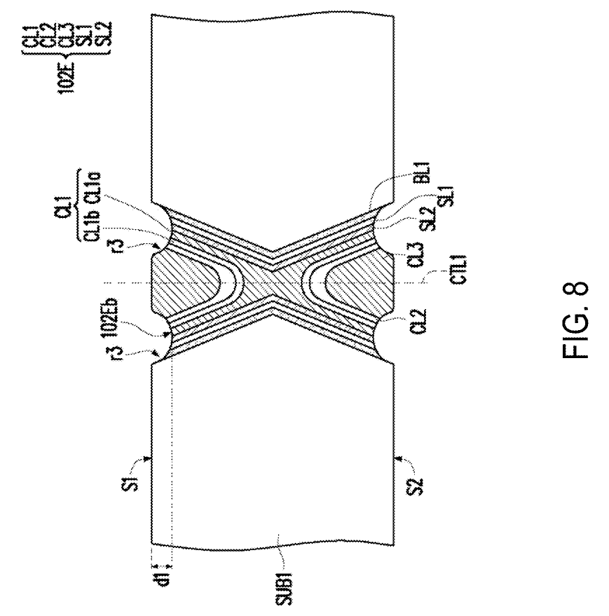

FIGS. 6, 7 and 8 are schematic cross-sectional views of conductive elements according to different embodiments of the present disclosure. The conductive element 102C shown in FIG. 6, the conductive element 102D shown in FIG. 7, and the conductive element 102E shown in FIG. 8 are similar to the conductive element 102B shown in FIG. 4. The difference is that the conductive elements 102C, 102D, and 102E have uneven recesses, protrusions, or slits. Other same or similar elements are denoted by the same or similar element symbols, and their redundant descriptions are not repeated here.

Please refer to FIG. 6. The buffer layer BL1 may be disposed between the conductive element 102C and the substrate SUB1. In this embodiment, the electronic device 10 may comprise a slit Slit1 disposed in the conductive element 102C. For example, the conductive element 102C may have a slit Slit1 that passes through its center in the Z-direction but does not adversely affect its conductive properties. In this embodiment, the slit Slit1 extends along a centerline CTL1 of the conductive element 102C. In this embodiment, the conductive element 102C may comprise a first recess r1 and a second recess r2 whose centers overlap with the centerline CTL1, wherein the first recess r1 is formed in the second recess r2 such that a lowest position 102Cb of the conductive element 102C is located at a bottom end of the first recess r1. In this embodiment, a level of the upper surface S1 (or the lower surface S2) is spaced apart from the lowest position 102Cb (i.e., the bottom end of the first recess r1) by a first distance d1, wherein the first distance d1 is less than or equal to 5 micrometers. This ensures that the first recess r1 and the second recess r2 in the conductive element 102C do not adversely affect its conductive properties or subsequent processes. According to some embodiments, the slit Slit1 can be formed by laser, etching, or other suitable methods. In some of the embodiment, in the cross-section view the Slit1 may be surrounded by the conductive layer 104, and a ratio of a volume of the Slit1 to a volume of the through hole is less than or equal to 0.5, for example, a ratio of a volume of the Slit1 to a volume of the through hole is greater than or equal to 0.4 and less than 0.5, which is not only to enhance the electrically quality but decrease the risk of crack.

Please refer to FIG. 7. The conductive element 102D may comprise a protrusion 102Dp and a recess 102Db. In this embodiment, relative to a centerline CTL1 passing through the center of the conductive element 102D, the protrusion 102Dp and the recess 102Db are distributed at a periphery of the conductive element 102D adjacent to the upper surface S1 (or the lower surface S2) of the substrate SUB1. A lowest position of the conductive element 102D is at a bottom end of the recess 102Db, and a highest position of the conductive element 102C is at a top end of the protrusion 102Dp. In this embodiment, a level of the upper surface S1 (or the lower surface S2) is spaced apart from the bottom end of the recess 102Db by a first distance d1, and is spaced apart from the top end of the protrusion 102Dp by a second distance d2. The first distance d1 and the second distance d2 are less than or equal to 5 micrometers, which ensures that the protrusion 102Dp and the recess 102Db in the conductive element 102D do not adversely affect its conductive properties or subsequent processes.

Please refer to FIG. 8. The conductive element 102E may comprise a recess r3. In this embodiment, relative to a centerline CTL1 passing through the center of the conductive element 102E, the recess r3 is distributed at a periphery of the conductive element 102D adjacent to the upper surface S1 (or the lower surface S2) of the substrate SUB1. A lowest position 102Eb of the conductive element 102E is located at a bottom end of the recess r3. In this embodiment, the upper surface S1 (or the lower surface S2) is spaced apart from the lowest position 102Eb by a first distance d1, wherein the first distance d1 is less than or equal to 5 micrometers. This ensures that the recess r3 in the conductive element 102E does not adversely affect its conductive properties or subsequent processes.

FIG. 9 is a schematic cross-sectional view of an electronic device according to another embodiment of the present disclosure. The electronic device 20 shown in FIG. 9 is similar to the electronic device 10 shown in FIG. 1. The differences are that the electronic device 20 comprises a buffer layer 150 and a mark MK1, and a connection component 160 is different from the connection component 140 of the electronic device 10.

Please refer to FIG. 9. The buffer layer 150 may be disposed on the first surface 100S1 and the second surface 100S2 of the substrate 100 and extend into the through-hole 101. The mark MK1 may be disposed in the substrate 100 and can be used as an alignment mark in the process of bonding the connection component 160. The buffer layer 150 may comprise the materials used for the aforementioned buffer layers BL1, BL2, or BL3.

In this embodiment, the connection component 160 may comprise a connection substrate 161, a conductive element 162 penetrating the connection substrate 161, a buffer layer 170 disposed between the conductive element 162 and the connection substrate 161, and circuit structures CS1 and CS2 disposed on opposite surfaces of the connection substrate 161. In this embodiment, the circuit structure CS1 is electrically connected to the conductive element 102 through a bonding element BE2, and the circuit structure CS1 is electrically connected to the circuit structure CS2 through the conductive element 162. The connection substrate 161 may comprise the materials listed for the aforementioned substrate 100. The buffer layer 170 may comprise the materials used for the aforementioned buffer layers BL1, BL2, or BL3.

In this embodiment, the circuit structure CS1 may comprise an insulating layer IL1 formed on an upper surface of the connection substrate 161 and a wiring structure WL1 with multiple conductive patterns alternately stacked in the Z-direction. The circuit structure CS2 may comprise an insulating layer IL2 formed on a lower surface of the connection substrate 161 and a wiring structure WL2 with multiple conductive patterns alternately stacked in the Z-direction. The insulating layer IL1 and the insulating layer IL2 may each comprise the materials listed for the aforementioned insulating layer 112. The wiring structure WL1 and the wiring structure WL2 may each comprise the materials listed for the aforementioned wiring structure 114.

In this embodiment, the electronic device CL1b may comprise a bonding element BE3 disposed below the circuit structure CS2 and electrically connected to the circuit structure CS2. The bonding element BE3 may comprise the materials used for the aforementioned bonding element BE1. In this embodiment, the connection component 160 may comprise a protective layer PV1 disposed below the circuit structure CS2, wherein the protective layer PV1 may surround the connection pads in the wiring structure WL2 that are in contact with the bonding element BE3. In this embodiment, the protective layer PV1 can serve as a solder mask, allowing the surfaces of the connection pads in the wiring structure WL2 exposed by the protective layer PV1 to have good contact with the bonding element BE3. This can help improve the reliability of the electronic device 20. In some embodiments, the protective layer PV1 may comprise any suitable organic or inorganic material to be used as a solder mask.

The above embodiments are only for illustrating the technical solutions of the present disclosure, not for limiting them. Although the embodiments of the present disclosure and their advantages have been disclosed as above, those skilled in the art can make modifications, substitutions, and refinements without departing from the spirit and scope of the present disclosure, and the features of each embodiment can be arbitrarily mixed and replaced to form other new embodiments. In addition, the scope of protection of the present disclosure is not limited to the processes, machines, manufacturing, compositions of matter, devices, methods, and steps in the specific embodiments in the specification. Those skilled in the art can understand from the disclosure of the present disclosure that existing or future developed processes, machines, manufacturing, compositions of matter, devices, methods, and steps can be used according to the present disclosure as long as they can perform substantially the same function or obtain substantially the same result as implemented in the embodiments herein. Furthermore, each claim constitutes a separate embodiment, and the scope of protection of the present disclosure also includes combinations of various claims and embodiments. The scope of protection of the present disclosure should be defined by the appended claims.

What is claimed is:

1. An electronic device, comprising:
a substrate, comprising a first surface and a second surface opposite to each other in a first direction;
two adjacent through-holes, penetrating the substrate, wherein a first spacing exists between the two adjacent through-holes along a second direction perpendicular to the first direction, and the first spacing is less than or equal to 200 micrometers;
a conductive element, disposed in one of the two adjacent through-holes;
a circuit structure, disposed on the substrate; and
an electronic unit, disposed on the circuit structure and electrically connected to the conductive element through the circuit structure,
wherein the conductive element comprises a first portion adjacent to the circuit structure, and in a cross-sectional view, the first portion has a first average grain size measured before the circuit structure is formed on the substrate, the first average grain size being less than or equal to 5 micrometers.

2. The electronic device of claim 1, wherein in a top view, the first portion has a second average grain size measured before the circuit structure is formed on the substrate, and the second average grain size is less than or equal to 6 micrometers.

3. The electronic device of claim 1, wherein in the cross-sectional view, the first portion has a first grain size distribution measured after the circuit structure is formed on the substrate, and the first grain size distribution ranges from 0.1 micrometers to 20 micrometers.

4. The electronic device of claim 1, further comprising:
a buffer layer, disposed between the substrate and the conductive element.

5. The electronic device of claim 4, wherein in the cross-sectional view, the first portion has a second grain size distribution measured after the circuit structure is formed on the substrate, and the second grain size distribution ranges from 20 micrometers to 60 micrometers.

6. The electronic device of claim 1, further comprising:
another through-hole, penetrating the substrate and adjacent to a first through-hole of the two adjacent through-holes,
wherein a second spacing exists between the another through-hole and the first through-hole, the second spacing is less than or equal to 200 micrometers and is different from the first spacing.

7. The electronic device of claim 1, wherein the two adjacent through-holes have a first dimension at the first surface or the second surface of the substrate, and a ratio of the first dimension to the first average grain size ranges from 4 to 24.

8. The electronic device of claim 1, wherein the two adjacent through-holes have a second dimension at a waist portion between the first surface and the second surface of the substrate, and a ratio of the second dimension to the first average grain size ranges from 3 to 23.

9. The electronic device of claim 1, wherein the conductive element comprises a recess, a bottom end of the recess is spaced apart from a level of the first surface or the second surface by a first distance, and the first distance is less than or equal to 5 micrometers.

10. The electronic device of claim 1, wherein the conductive element comprises a protrusion, and a top end of the protrusion is spaced apart from a level of the first surface or the second surface by a second distance, the second distance being less than or equal to 5 micrometers.

11. The electronic device of claim 1, wherein the substrate comprises glass.

12. The electronic device of claim 1, wherein the conductive element comprises copper.

13. The electronic device of claim 4, wherein a surface roughness of the buffer layer is less than a roughness of a sidewall of one of the two adjacent through-holes.

14. The electronic device of claim 1, further comprising an encapsulation layer surrounding the electronic unit and the circuit structure.

15. The electronic device of claim 13, wherein the roughness of a sidewall of one of the two adjacent through-holes is less than the roughness of the first surface.

16. The electronic device of claim 1, wherein the substrate has a coefficient of thermal expansion (CTE) ranging from 2 ppm/°C to 10 ppm/°C.

17. The electronic device of claim 7, wherein a ratio of a thickness of the substrate to the first dimension is greater than or equal to 6 and less than or equal to 16.

18. The electronic device of claim 1, further comprises a slit disposed in the conductive element.

19. The electronic device of claim 18, wherein a ratio of a volume of the slit to a volume of the one of the two adjacent through-holes is less than 0.5.

20. The electronic device of claim 1, wherein the substrate further comprises an alignment mark disposed in the substrate.
